(19) United States
(12) Patent Application Publication
(10) Pub. No.: US 2025/0280601 A1
(43) Pub. Date: Sep. 4, 2025

(54) STACKED FET WITH STACKED POWER RAIL

(71) Applicant: INTERNATIONAL BUSINESS MACHINES CORPORATION, Armonk, NY (US)

(72) Inventors: Ruilong Xie, Niskayuna, NY (US); David Wolpert, Poughkeepsie, NY (US); Brent A. Anderson, Jericho, VT (US); Albert M. Chu, Nashua, NH (US); Lawrence A. Clevenger, Saratoga Springs, NY (US); Nicholas Anthony Lanzillo, Wynantskill, NY (US)

(21) Appl. No.: 18/593,388

(22) Filed: Mar. 1, 2024

(51) Int. Cl. H01L 27/12

(52) U.S. Cl. CPC H10D 86/60; H10D 86/0214; H10D 86/441

(57) ABSTRACT

A semiconductor device includes a stacked transistor structure having field effect transistors on two levels. The two levels include a top side and bottom side. A bottom power rail is disposed on the bottom side between source/drain regions of the field effect transistors, and a top power rail is disposed on the top side between source/drain regions of the field effect transistors.

### BACKGROUND

The present invention generally relates to semiconductor devices and processing methods, and more particularly to stacked field effect transistors (FETs) with stacked power rails, where the stacked power rails are disposed within a same level as gates and source/drain diffusion regions.

Stacked transistor devices may be used to increase areal density of devices on a chip. Additionally, the close proximity of the overlying and underlying devices can be useful when forming paired devices, such as complementary semiconductor devices that include two devices of opposing polarity. However, positioning transistors above one another places spatial and electrical constraints, which can make it challenging to provide required performance.

In current stacked field effect transistor (FET) definition, all backside power connections are difficult as risk of shorts to gates or other conductive structures is extremely high. Current practices include forming deep contacts or connections from a frontside or a backside of a device. These contacts pass through regions including other conductive structures. As such, these contacts can easily short to the conductive structures through which they pass. These issues are even more pronounced when further reduction in device pitches (contacted poly pitch (CPP)) and devices sizes are introduced.

Therefore, a need exists for placement of power rails that increases reliability by decreasing risks associated with shorts between adjacent structures in a stacked FET device.

### SUMMARY

In accordance with an embodiment of the present invention, a semiconductor device includes a stacked transistor structure having field effect transistors on two levels. The two levels include a top side and bottom side. A bottom power rail is disposed on the bottom side between source/drain regions of the field effect transistors, and a top power rail is disposed on the top side between source/drain regions of the field effect transistors.

In other embodiments, the bottom power rail and the top power rail can be vertically disposed relative to one another. The bottom power rail and the top power rail can be separated by a power rail barrier. The bottom power rail can connect to a bottom source/drain region. The top power rail can connect to a top source/drain region. The bottom power rail and the top power rail together can provide positive and negative supply voltages. The bottom power rail and the top power rail can provide positive supply voltages. The bottom power rail and the top power rail can provide negative supply voltages.

In accordance with another embodiment of the present invention, a semiconductor device includes a stacked transistor structure having field effect transistors on at least two levels, the at least two levels including a top side and bottom side. A stacked power rail is disposed between the field effect transistors on the at least two levels. The stacked power rail has a bottom power rail electrically isolated from surrounding structures by a first dielectric spacer and a top power rail electrically isolated from surrounding structures by a second dielectric spacer.

In other embodiments, the bottom power rail and the top power rail can be separated by a power rail barrier. The bottom power rail can connect to a bottom source/drain region. The top power rail can connect to a top source/drain region. The bottom power rail and the top power rail can together provide positive and negative supply voltages. The bottom power rail and the top power rail can provide positive supply voltages. The bottom power rail and the top power rail can provide negative supply voltages.

In accordance with another embodiment of the present invention, a semiconductor device, includes a stacked transistor structure having field effect transistors on at least two levels, the at least two levels including a top side and bottom side and a stacked power rail disposed between the field effect transistors on the at least two levels. The stacked power rail has a bottom power rail electrically isolated from the field effect transistors and gates by a first dielectric spacer. The bottom power rail is connected to a backside power rail. A top power rail is electrically isolated from the field effect transistors and gates by a second dielectric spacer. The top power rail is connected to a frontside component. A power rail barrier connects the first dielectric spacer and the second dielectric spacer and electrically separates the top power rail from the bottom power rail.

In other embodiments, the bottom power rail can connect to a bottom source/drain region. The top power rail can connect to a top source/drain region. The bottom power rail and the top power rail can together provide positive and negative supply voltages. The bottom power rail and the top power rail can provide a same supply voltage.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows cross-sectional views, taken at section lines X, Y1 and Y2 as shown in an inset (and referred to as section X, section Y1 and section Y2, respectively), of a stacked FET semiconductor device, in accordance with an embodiment of the present invention;

FIG. 2 shows cross-sectional views, taken at section lines X, Y1 and Y2, showing a cut formed between devices (e.g., between CMOS cells) and dividing gate structures, in accordance with an embodiment of the present invention;

FIG. 3 shows cross-sectional views, taken at section lines X, Y1 and Y2, showing a first dielectric spacer formed in the cut, in accordance with an embodiment of the present invention;

FIG. 4 shows cross-sectional views, taken at section lines X, Y1 and Y2, showing the first dielectric spacer patterned to open up a window in the cut, in accordance with an embodiment of the present invention;

FIG. 5 shows cross-sectional views, taken at section lines X, Y1 and Y2, showing the first dielectric spacer filled to form a bottom power rail, in accordance with an embodiment of the present invention;

FIG. 6 shows cross-sectional views, taken at section lines X, Y1 and Y2, showing a second dielectric spacer formed, patterned and filled to form a top power rail in a stacked power rail configuration, in accordance with an embodiment of the present invention;

FIG. 7 shows cross-sectional views, taken at section lines X, Y1 and Y2, showing middle of the line contacts formed, back end of the line structures formed and a carrier wafer bonded to a frontside of the stacked FET semiconductor device, in accordance with an embodiment of the present invention;

FIG. 8 shows cross-sectional views, taken at section lines X, Y1 and Y2, after a substrate has been removed to an etch stop layer on a bottom side, in accordance with an embodiment of the present invention;

FIG. 9 shows cross-sectional views, taken at section lines X, Y1 and Y2, after a semiconductor layer is recessed by etching, in accordance with an embodiment of the present invention; and

FIG. 10 shows cross-sectional views, taken at section lines X, Y1 and Y2, after a backside interlevel dielectric layer is formed, a backside power rail is formed and a backside interconnect layer is formed, in accordance with an embodiment of the present invention.

### DETAILED DESCRIPTION

In accordance with embodiments of the present invention, devices and methods are described which include placement of power rails within regions that include epitaxially formed structures or epitaxial regions (epi regions) in a stacked field effect transistor (FET) device. Power rails are vertically stacked in a column to provide a front power rail aligned with a back power rail. The front power rail can be disposed adjacent to and/or can connect with one or more top epi regions. The bottom power rail can be disposed adjacent to and/or can connect with one or more bottom epi regions. The top power rail and the bottom power rail are electrically isolated from one another by a dielectric layer disposed therebetween.

A stacked FET can include one transistor stacked over another transistor. A cut region can be disposed between two levels of FETs, where the cut region separates two neighboring complementary metal oxide semiconductor (CMOS) cells. The top power rail stacks over the bottom power rail in the cut region. Both the top power rail and the bottom power rail are isolated from gates by a dielectric spacer formed on lateral portions of the cut region. The top power rail and the bottom power rail can be isolated from one another by the same dielectric spacer.

The top power rail can connect a top source/drain region (S/D) to a frontside back end of the line (BEOL) component. The bottom power rail can connect a bottom S/D region to a backside interconnect or other conductive structure. The dielectric spacer can also include a power rail barrier portion that can be employed to isolate the top power rail and/or the bottom power rail from other S/D regions. The top power rail can be a negative supply voltage (VSS) rail or a positive supply voltage (VDD) rail. The bottom power rail can be a negative supply voltage (VSS) rail or a positive supply voltage (VDD) rail. In other embodiments, the top and bottom power rails can both be VSS rails or can both be VDD rails.

In an embodiment, a method for forming a semiconductor device can include forming stacked FETs with a first transistor over a second transistor and forming a cut between two neighboring CMOS cells. The cut can have a dielectric spacer formed therein. Portions of the dielectric spacer are removed for a connection to a bottom S/D region. A bottom power rail is formed by depositing a conductive material over portions of the dielectric spacer within the cut. The dielectric spacer is extended over the bottom power rail. Portions of the dielectric spacer are removed for a connection to a top S/D region. A top power rail is formed by depositing a conductive material over portions of the dielectric spacer within the cut. In an embodiment, the top power rail is connected to a frontside BEOL component, and the bottom power rail is connected to a backside interconnect.

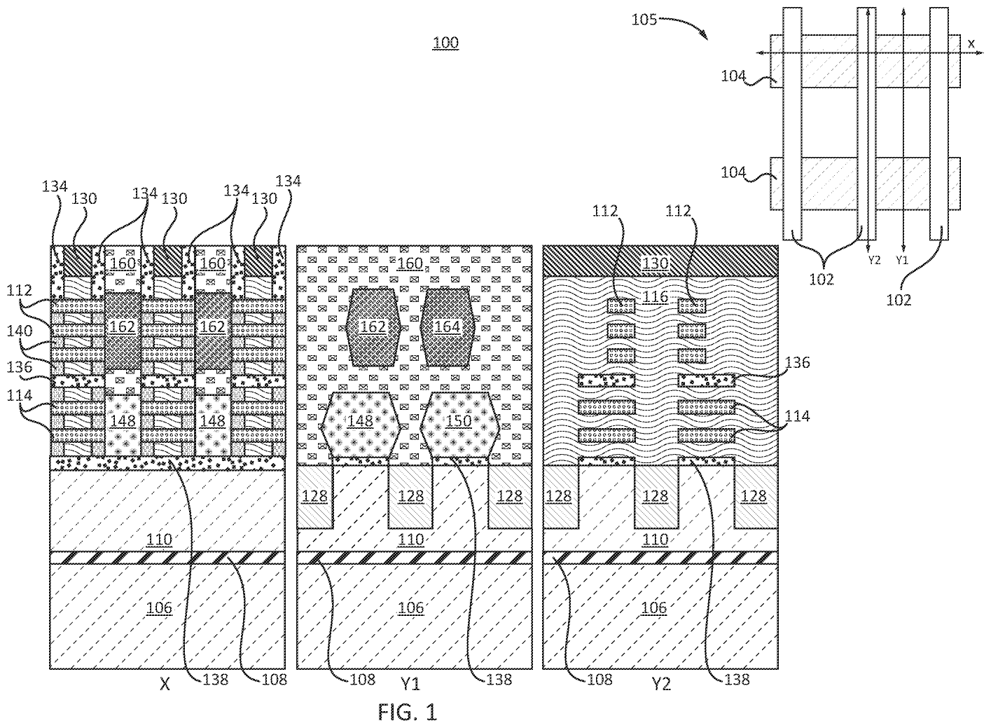

Referring now to the drawings in which like numerals represent the same or similar elements and initially to FIG. 1, devices and methods for manufacturing a stacked field effect transistor (FET) device are shown in accordance with embodiments of the present invention. A wafer 100 includes a substrate 106 having multiple layers on which the stacked FET device will be fabricated. FIG. 1 depicts views X, Y1 and Y2 taken at corresponding sections X, Y1 and Y2 in inset 105. Inset 105 shows gate lines 102 and active region lines 104 for reference. Corresponding X, Y1 and Y2 views are depicted throughout FIGS. 1-10. Active region lines 104 represent S/D regions for transistor devices to be formed. Gate lines 102 are represented for such transistor devices associate with the active region lines 104. Transistor channels are formed on the active region lines 104 below the gate lines 102. It should be understood that active region lines 104 and gate lines 102 show the orientation of two levels of stacked FET devices and two levels of gate structures.

The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 108 is formed within the substrate 106. The etch stop layer 108 can include an epitaxially grown crystal structure. The etch stop layer 108 includes a material that permits the selective etching and removal of the substrate 106 in later steps. In an embodiment, the etch stop layer 108 includes SiGe although depending on the material of the substrate 106, other materials can be selected, e.g., SiGeC, SiC, etc.

A semiconductor layer 110 is epitaxially grown on the etch stop layer 108. The semiconductor layer 110 can include a same material as the substrate 106, although other semiconductor materials can be employed, e.g., SiGe, SiGeC, SiC, etc.

A layer stack or stacks are applied to or formed on the semiconductor layer 110. In one embodiment, one or more nanosheets (NS) are applied to the semiconductor layer 110. In another embodiment, the layer stacks can be epitaxially grown using different chemistries to form layers having different properties. The nanosheet can be processed to form semiconductor layers 112, which will be employed as device channels for top FETs, and semiconductor layers 114, which will be employed as device channels for bottom FETs.

Semiconductor layers 112 and 114 can include Si. It should be understood that other materials can be employed for semiconductor layers 112, 114. In other embodiments, different stack orders and numbers may be employed for semiconductor layers 112, 114.

Shallow trench isolation (STI) or STI regions 128 can be formed in etched trenches using a hard mask on the nanosheet to pattern the STI regions 128. STI regions 128 can be formed by depositing dielectric material, such as, e.g., SiO₂, SSiOₓN_{y}, SiCO or other suitable compounds. STI regions 128 can be deposited using chemical vapor deposition (CVD), although other deposition methods can be employed. The STI regions 128 can then be etched, e.g., by RIE, to a level of the semiconductor layer 110.

A gate electrode 116 is used to replace a dummy gate material (not shown) in a gate structure fabrication method known as a replacement gate method. The dummy gate material can include a polysilicon, amorphous Si or other selectively removeable material. The dummy gate material along with patterning process are employed in the formation of spacers 134, middle dielectric interface (MDI) 136 and bottom dielectric interface (BDI) 138 to fill empty regions where semiconductor layers 112 and 114 were removed at the indicated locations. Spacers 134, MDI 136 and BDI 138 can include an oxide, such as silicon dioxide, or nitride, such as silicon nitride, although other dielectric materials can be employed and depend on surrounding materials.

Inner spacers 140 are formed and include a dielectric material. In one embodiment, the inner spacers 140 are formed using exposed portions of a SiGe semiconductor layer disposed between semiconductor layers 112 and 114 in an alternating pattern. Inner spacers 140 can be formed by selective SiGe indentation followed by inner spacer material fill and etch back.

Self-aligned caps (SACs) 130 can be formed over the gate electrode 116. The SACs 130 can include a dielectric materials, such as, for example, SiN, although other suitable dielectrics can be employed.

Prior to formation of the gate electrode 116, a high dielectric constant (high-K) gate dielectric is formed over the semiconductor layers 112 and 114 prior to a gate metal fill. This process is known as a High-K Metal Gate (HKMG) process and forms gate structures for selectively activating top FETs and bottom FETs. The gate structures are separated by MDI 136 and the FETs are separated by a dielectric layer 160 (e.g., an interlevel dielectric layer (ILD)).

An epitaxial growth process can be performed to form bottom source/drain regions 148 and 150 using semiconductor layers 114 to initiate crystal growth. Bottom source/drain regions 148 and 150 are employed for bottom transistors or FETs of the stacked FET device under construction. Bottom source/drain regions 148 and 150 can include Si or SiGe and include faceted surfaces when epitaxial growth is not confined. In one embodiment, the bottom source/drain regions 148 and 150 can be designated as P-type or N-type devices. If the bottom source/drain regions 148 and 150 include N-type devices than the bottom source/drain regions 148 and 150 can include Si. If the bottom source/drain regions 148 and 150 include P-type devices than the bottom source/drain regions 148 and 150 can include SiGe.

The bottom source/drain regions 148 and 150 can be appropriately doped during the formation of the bottom source/drain regions 148 and 150 by epitaxial growth. For example, the bottom source/drain regions 148 and 150 can be doped by introducing p dopants (e.g., B, Ga, etc.) during epitaxial formation. Similarly, the bottom source/drain regions 148 and 150 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device during processing of the other. In such an instance, fill materials will also be appropriately applied depending on the device type.

Another epitaxial growth process is employed to grow top active regions 162 and 164. Top active regions 162 and 164 will form source/drain regions for top transistors or FETs for the stacked FET device under fabrication. The top active regions 162, 164 can utilize the semiconductor layers 112 to initiate crystal growth. The top active regions 162, 164 and the bottom source/drain regions 148, 150 are encapsulated in one or more dielectric layers 160.

The dielectric layer 160 (ILD) can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α—C:H). The dielectric layer 160 can be deposited using CVD, although other deposition methods can be employed.

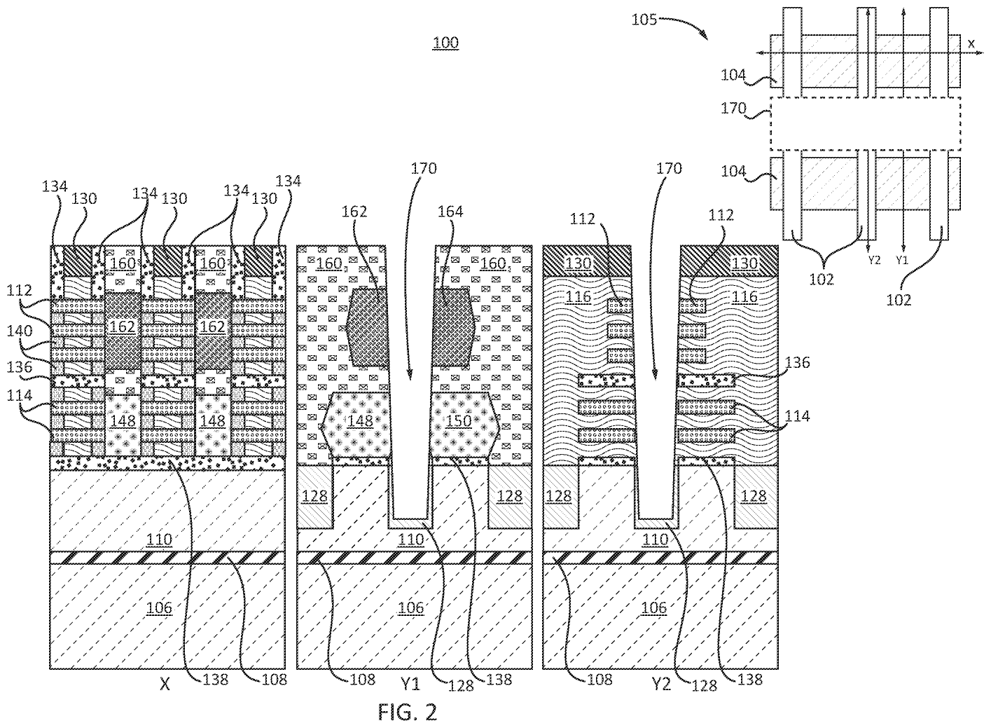

Referring to FIG. 2, an accurately controlled patterning process is employed to open up a cut 170. In an embodiment, a reactive ion etch (RIE) process is employed to selectively remove material to form the cut 170. The cut 170 separates top source/drain regions 162 and 164 as well as bottom source/drain regions 148 and 150 (see, section Y1). The cut 170 also divides the gate electrode 116 (see section Y2). The cut 170 continues into the STI region 128 but stops before breaking through to the substrate layer 110.

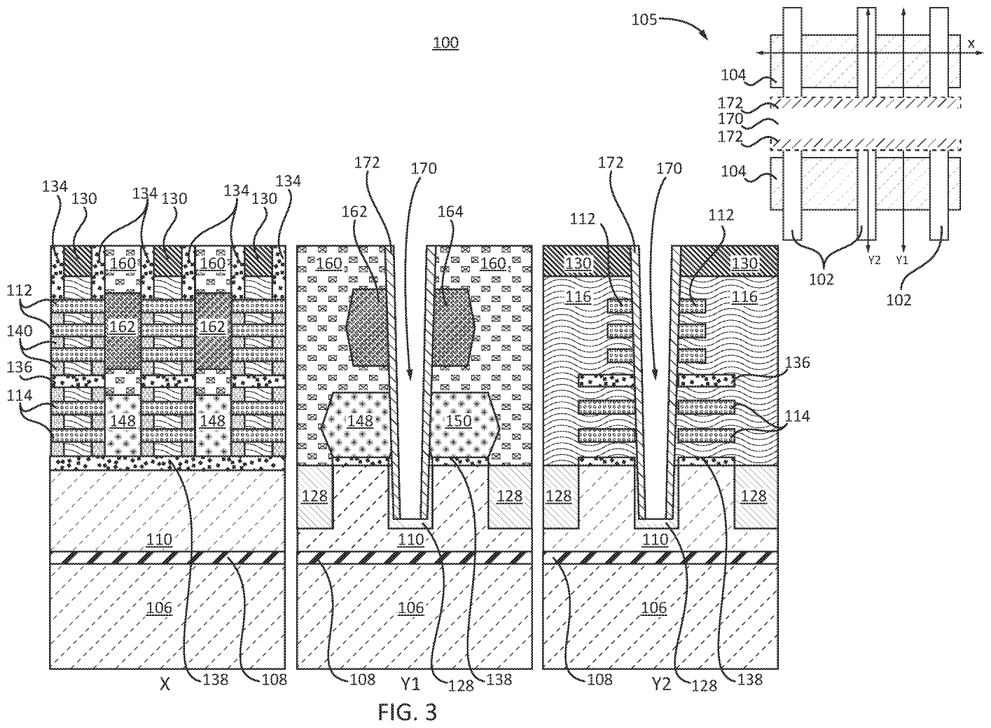

Referring to FIG. 3, a dielectric layer is deposited over the wafer 100. The dielectric layer covers a top surface of the wafer 100 and lines the cut 170. The dielectric layer is then subjected to a spacer etch, e.g., RIE, to remove the dielectric layer from horizontal surfaces to form a dielectric spacer 172 along sidewalls of the cut 170. The dielectric spacer 172 can include silicon nitride, silicon oxynitride or other suitable dielectric materials.

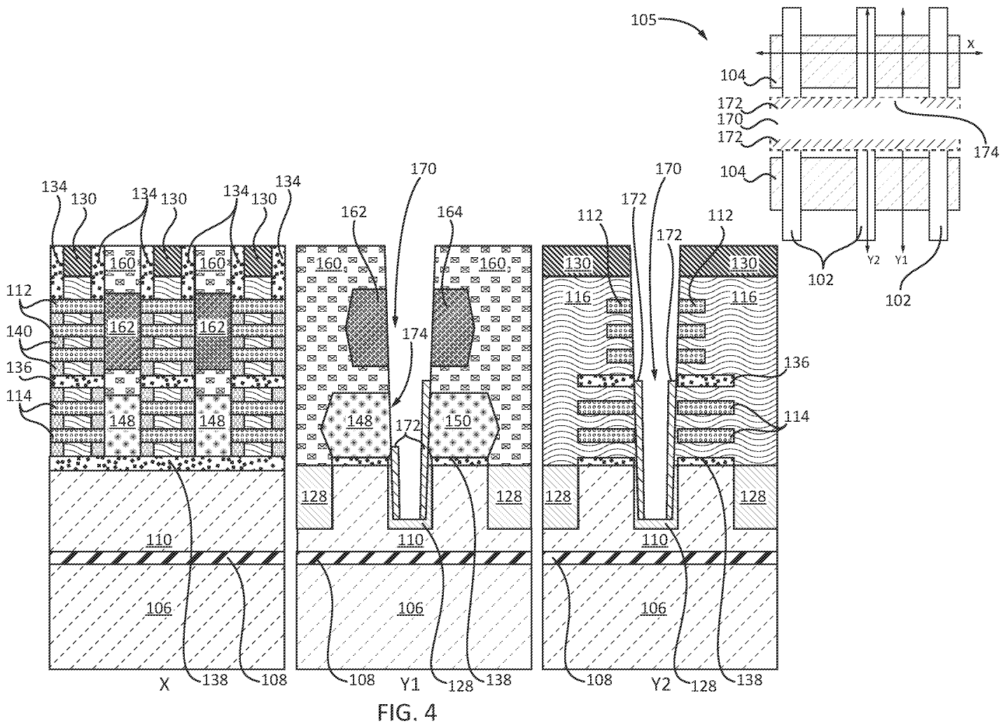

Referring to FIG. 4, the dielectric spacer 172 is configured to permit access therethrough to the bottom source/drain region 148. The dielectric spacer 172 can be configured using a number of different techniques. In an example, the cut 170 could be filled with a material and the dielectric spacers 172 can be recessed to a level of the material just above the bottom source/drain regions 148 and 150. Then, a patterning process can be employed to cover a portion of the dielectric spacer 172 leaving a portion exposed for etching. The dielectric spacer 172 can then be etched to open up a window 174 in the dielectric spacer 172. The window 174 will permit access from inside the cut 170 to permit contact with the bottom source/drain region 148. The material and any etch mask(s) are then removed.

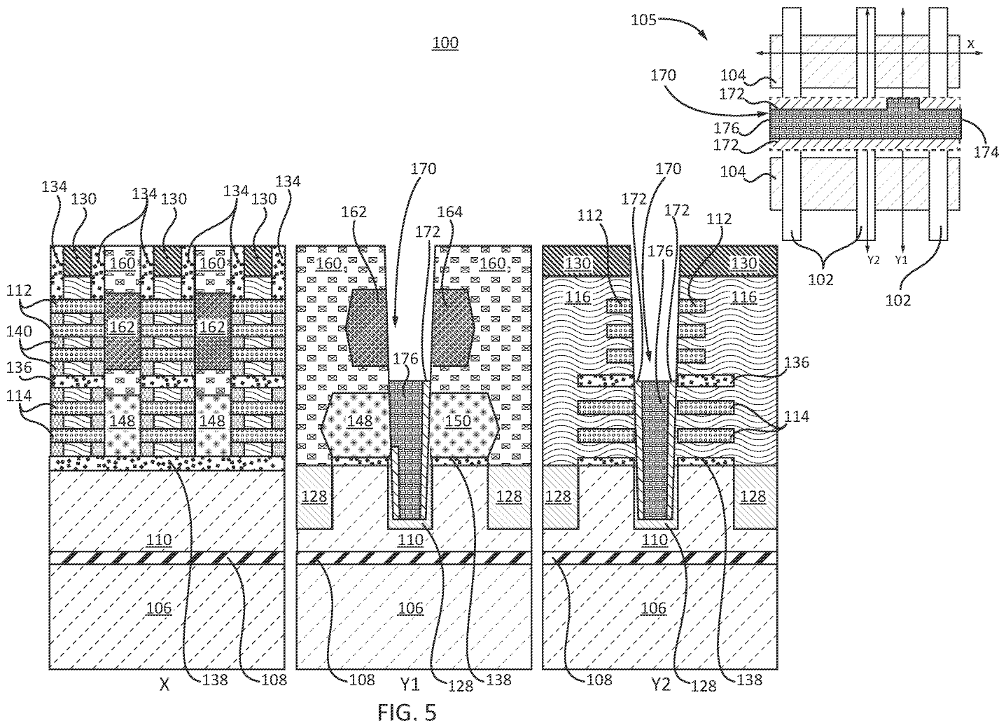

Referring to FIG. 5, a conductive fill is performed to fill in the cut 170. The conductive fill is recessed by an etch process to recess the conductive fill to a top of the dielectric spacer 172. This forms a bottom power rail 176 in the cut 170. In the illustrative embodiment shown, the bottom power rail 176 makes electrical contact to a single bottom source/drain region 148. In this example, this bottom source/drain region 148 is directly contacted by the bottom power rail 176. The source/drain region 150 is isolated from the bottom power rail 176 by the dielectric spacer 172.

The conductive fill that forms bottom power rail 176 can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method.

In some embodiments, a silicide liner, such as Ti, Ni, NiPt can be deposited first (e.g., before the conductive fill) to improve conductive contact with the bottom source/drain region 148. A diffusion barrier can also be formed after the silicide liner (if present) and prior to the conductive fill. The diffusion barrier can include, e.g., TiN, TaN, or similar materials.

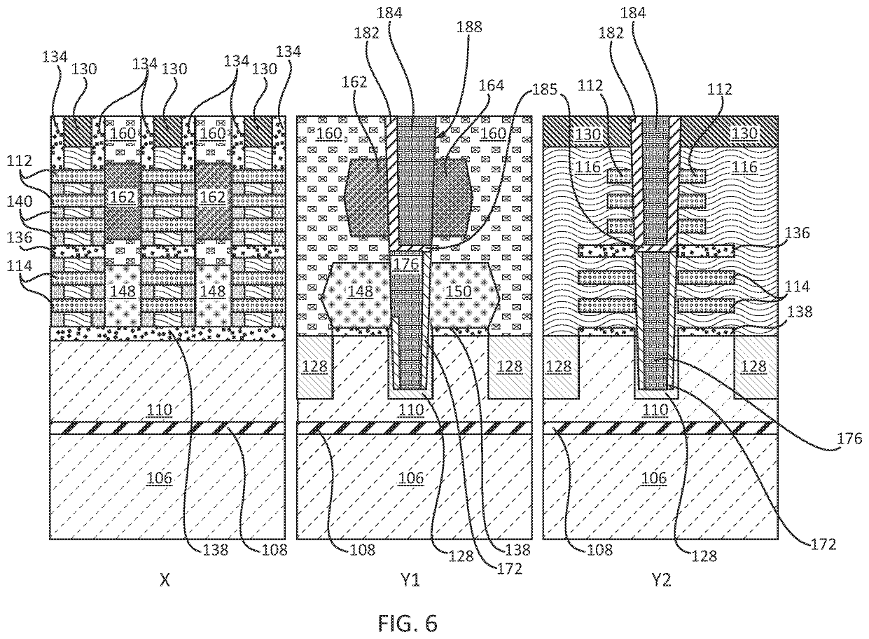

Referring to FIG. 6, another dielectric spacer 182 is formed over the wafer 100. The dielectric spacer 182 lines a top portion of the cut 170. Then, a patterning process can be employed to cover a portion of the dielectric spacer 182 leaving a portion exposed for etching. The dielectric spacer 182 can then be etched to open up an opening or window 188 in the dielectric spacer 182. The window 188 will permit access from inside the cut 170 to permit contact with the top source/drain region 164. Any etch mask(s) are then removed.

A conductive fill is performed to fill a top portion of the cut 170 on the dielectric spacer 182. A rail barrier portion 185 of the dielectric spacer 182 is disposed between the top portion and the bottom rail 176. The rail barrier portion 185 provides separation and dielectric isolation between the bottom rail 176 and a top rail 184. The conductive fill is recessed by an etch process or a planarization process to recess the conductive fill (and portion of the dielectric spacer 182) to a top surface of the wafer 100. This forms the top power rail 184 in the cut 170. In the illustrative embodiment shown, the top power rail 184 makes electrical contact to a single top source/drain region 164. In this example, this top source/drain region 164 is directly contacted by the top power rail 184. The source/drain region 162 is isolated from the top power rail 184 by the dielectric spacer 182.

The conductive fill that forms the top power rail 184 can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method.

In some embodiments, a silicide liner, such as Ti, Ni, NiPt can be deposited first (e.g., before the conductive fill) to improve conductive contact with the top source/drain region 164. A diffusion barrier can also be formed after the silicide liner (if present) and prior to the conductive fill. The diffusion barrier can include, e.g., TiN, TaN, or similar materials.

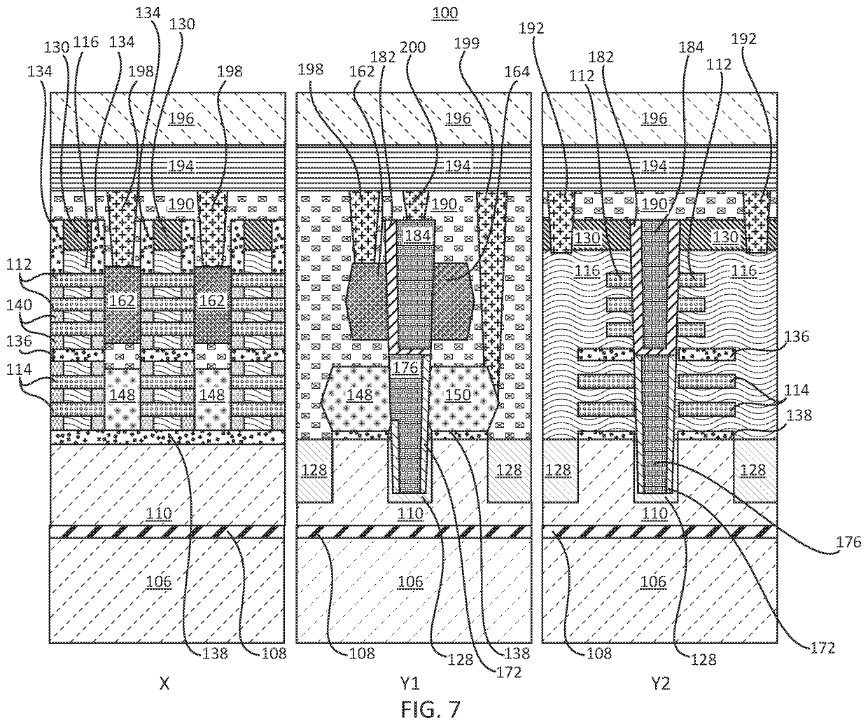

Referring to FIG. 7, a dielectric layer 190 is deposited over the wafer 100. The dielectric layer 190 can include a same material and process as the dielectric layer 160. A via 200 is formed through the dielectric layer 190 to connect to the top power rail 184. Middle of the line (MOL) contacts are formed through the dielectric layer 190. MOL contacts can include contacts 192 to gate electrodes 116, contacts 198 to top source/drain regions 162 and 164 and contacts 199 to the bottom source/drain regions 148, 150 from a top or frontside of the device. Trenches or holes are formed in the dielectric layer 190, which forms a top ILD. The trenches or holes expose the underlying active or conductive materials to permit the contacts to make conductive contact thereto.

In some embodiments, a silicide liner, such as Ti, Ni, NiPt is deposited first (e.g., for contacts 198 and 199). For all contacts and vias, a diffusion barrier can be formed in the trenches prior to a conductive fill. The diffusion barrier can include, e.g., TiN, TaN, or similar materials.

The conductive fill to form contacts 192, 198, 199 and via 200 can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to complete the contacts 192, 198, 199 and via 200.

Processing continues with the formation of back end of the line (BEOL) layer 194, which can include metal structures and dielectric layers to complete a top side of the stacked FET device and provide electrical access to the devices formed. A carrier wafer 196 can be bonded to the BEOL layer 194. The carrier wafer 196 provides support and transportability to the wafer 100 for further processing which includes flipping the wafer 100 and removing portions of a bottom side of the stacked FET device. The BEOL layer 194 includes metallization, structures and components which can be electrically connected to the contacts 192, 198, 199 and via 200.

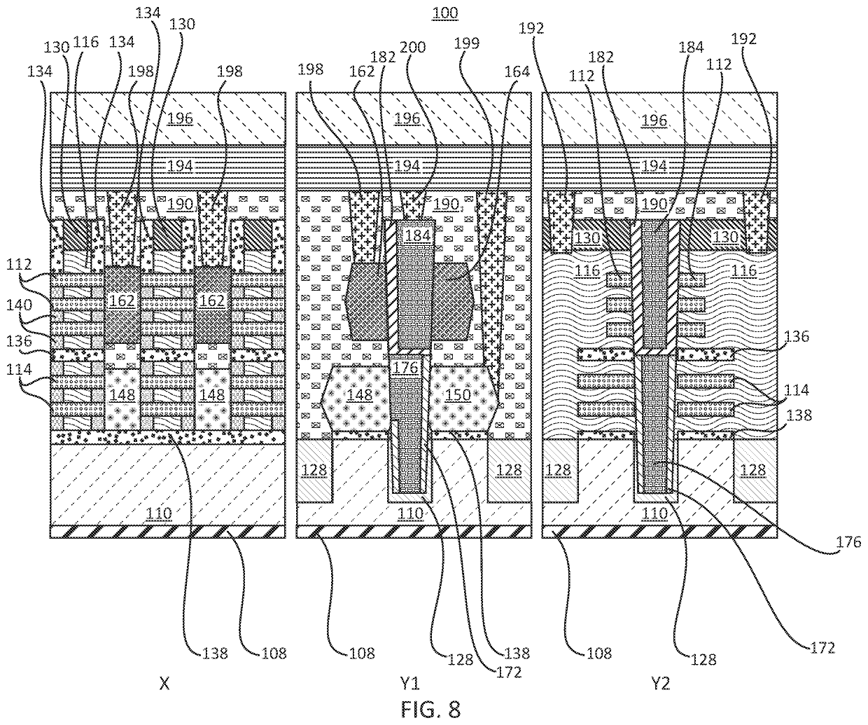

Referring to FIG. 8, to continue processing, the wafer 100 can be flipped to process features on the bottom or backside of the stacked FET device. However, for clarity and consistency, the stacked FET device will be shown in the FIGS. in a same orientation as previously described with continued and consistent reference to bottom/top. The substrate 106 is removed from the backside of the stacked FET device. The substrate 106 can be removed by an etch process that stops on the etch stop layer 108. In an alternate embodiment, a cleave process can be employed to propagate a crack to remove the substrate 106 at the etch stop layer 108.

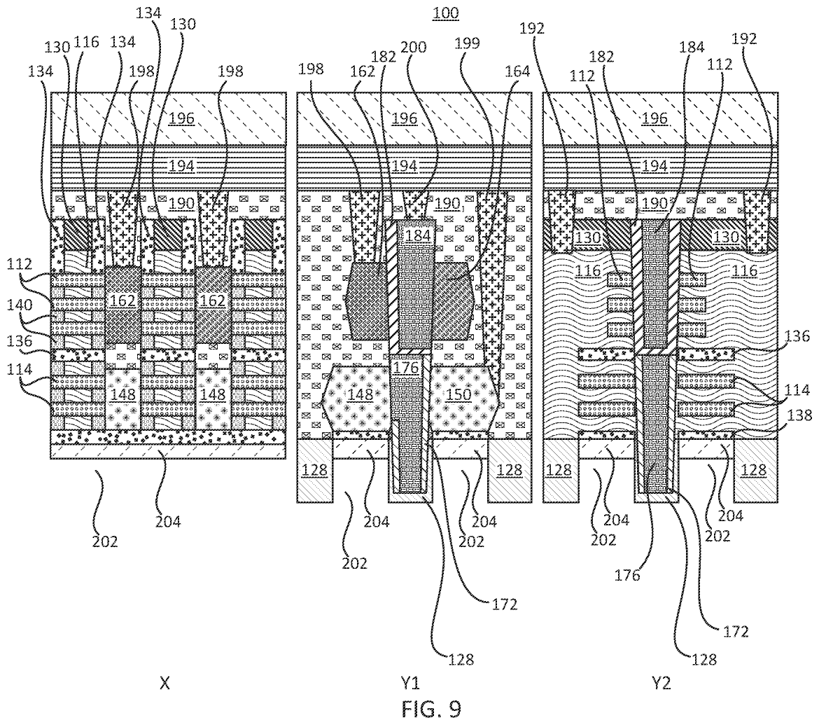

Referring to FIG. 9, the etch stop layer 108 is then removed by an etch process. In an alternate embodiment, a CMP process can be employed. With the removal of the etch stop layer 108, the semiconductor layer 110 is exposed. The semiconductor layer 110 is recessed by an etch process that selectively removes the material of the semiconductor layer 110 relative to the STI regions 128. The etch process opens up recesses 202. A portion 204 of the semiconductor layer 110 remains.

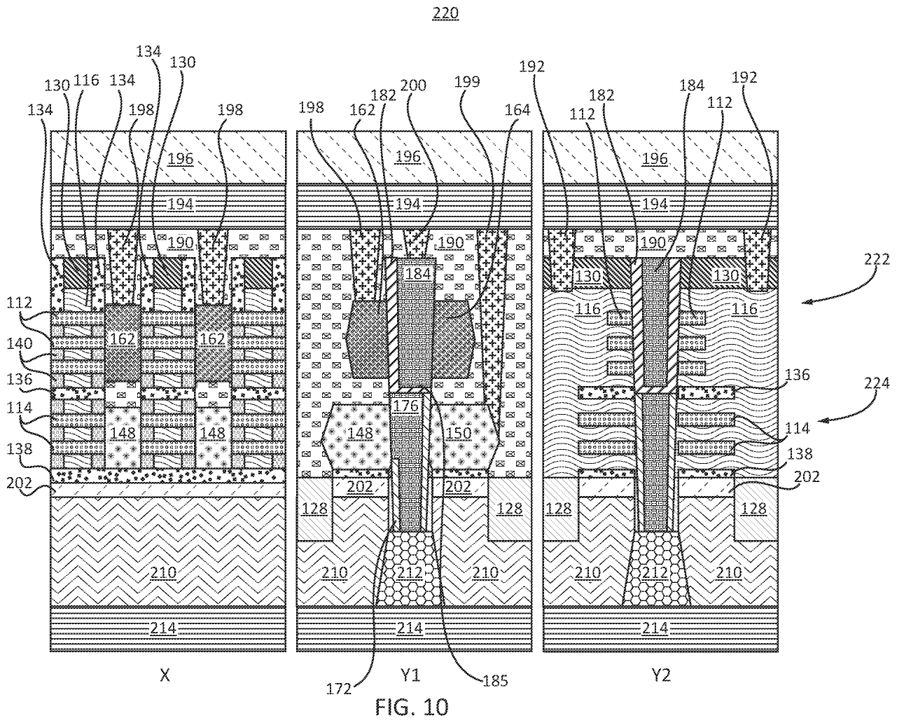

Referring to FIG. 10, a dielectric layer 210 (e.g., backside ILD or BILD) is formed over the STI regions 128 and portion 204. The dielectric layer 210 can include a silicon oxide, a silicon nitride, silicon oxynitride or any other suitable dielectric material. Trenches or holes are formed in the dielectric layer 210 to place a backside power rail (BSPR) 212.

Trenches or holes can be patterned using photolithographic patterning techniques to create an etch mask to etch the trenches or holes with an anisotropic etch., e.g., RIE. The trenches or holes expose the underlying bottom power rail 176, which is now exposed through the trenches or holes.

In an embodiment, a silicide liner, such as Ti, Ni, NiPt is deposited first, then a diffusion barrier can be formed in the trenches or openings prior to a conductive fill. The diffusion barrier can include, e.g., TiN, TaN, or similar materials. A conductive fill is performed to fill the trenches or openings. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the backside power rail 212.

Processing continues with the formation of a backside interconnect layer 214, which can include metal structures and dielectric layers to complete the bottom side of the stacked FET device and provide electrical access to the devices formed. The backside interconnect layer 214 is formed on the dielectric layer 210 and the backside power rail 212.

A stacked FET device 220 is provided having FETs formed in at least two layers 222 and 224. Layers 222 and 224 are separated by dielectric layer 160. Top FETs include top source/drain regions 162, 164 functioning as S/D regions activated by gate electrodes 116 in layer 222. Bottom FETs include bottom source/drain regions 148 and 150 functioning as S/D regions activated by gate electrode 116 in layer 224.

In accordance with embodiments of the present invention, each layer 222 and 224 includes a power rail within the level and disposed between and connected to one or more source/drain region to provide a stacked power rail structure. For example, the top power rail 184 is disposed within level or layer 222 along with top source/drain regions 162, 164. In addition, the bottom power rail 186 is disposed within level or layer 224 along with bottom source/drain regions 148, 150. The top power rail 184 and the bottom power rail 186 can occupy a same cut (e.g., cut 170) and can be separated by the rail barrier portion 185.

The top power rail 184 and the bottom power rail 186 are local to front end of line components and can provide local power connections. The local power connection can include connections to source/drain regions but also to any other components including metal lines, contacts, gate electrodes, etc. The top power rail 184 and the bottom power rail 186 can include windows or openings to make connections with surrounding components. In some embodiments, the top power rail 184 connects to a via 200 which, in turn, connects to one or more components in a BEOL layer 194. The bottom power rail 186 can connect to the backside power rail 212, which can connect to other components, e.g., in a backside interconnect layer 214.

The top power rail 184 can be employed to carry a negative supply voltage (VSS) or a positive supply voltage (VDD). Likewise, the bottom power rail 176 can be employed to carry VSS or VDD. In other embodiments, the top and bottom power rails can both be VSS rails or can both be VDD rails.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS, For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a stacked transistor structure having field effect transistors on at least two levels, the at least two levels including a top side and bottom side;
a bottom power rail disposed on the bottom side between source/drain regions of the field effect transistors; and
a top power rail disposed on the top side between source/drain regions of the field effect transistors.

2. The semiconductor device as recited in claim 1, wherein the bottom power rail and the top power rail are vertically disposed relative to one another.

3. The semiconductor device as recited in claim 1, wherein the bottom power rail and the top power rail are separated by a power rail barrier.

4. The semiconductor device as recited in claim 1, wherein the bottom power rail connects to a bottom source/drain region.

5. The semiconductor device as recited in claim 1, wherein the top power rail connects to a top source/drain region.

6. The semiconductor device as recited in claim 1, wherein the bottom power rail and the top power rail together provide positive and negative supply voltages.

7. The semiconductor device as recited in claim 1, wherein the bottom power rail and the top power rail provide positive supply voltages.

8. The semiconductor device as recited in claim 1, wherein the bottom power rail and the top power rail provide negative supply voltages.

9. A semiconductor device, comprising:
a stacked transistor structure having field effect transistors on at least two levels, the at least two levels including a top side and bottom side; and
a stacked power rail disposed between the field effect transistors on the at least two levels, the stacked power rail having:
a bottom power rail electrically isolated from surrounding structures by a first dielectric spacer; and
a top power rail electrically isolated from surrounding structures by a second dielectric spacer.

10. The semiconductor device as recited in claim 9, wherein the bottom power rail and the top power rail are separated by a power rail barrier.

11. The semiconductor device as recited in claim 9, wherein the bottom power rail connects to a bottom source/drain region.

12. The semiconductor device as recited in claim 9, wherein the top power rail connects to a top source/drain region.

13. The semiconductor device as recited in claim 9, wherein the bottom power rail and the top power rail together provide positive and negative supply voltages.

14. The semiconductor device as recited in claim 9, wherein the bottom power rail and the top power rail provide positive supply voltages.

15. The semiconductor device as recited in claim 9, wherein the bottom power rail and the top power rail provide negative supply voltages.

16. A semiconductor device, comprising:
a stacked transistor structure having field effect transistors on at least two levels, the at least two levels including a top side and bottom side; and
a stacked power rail disposed between the field effect transistors on the at least two levels, the stacked power rail having:
a bottom power rail electrically isolated from the field effect transistors and gates by a first dielectric spacer, the bottom power rail being connected to a backside power rail;
a top power rail electrically isolated from the field effect transistors and gates by a second dielectric spacer, the top power rail being connected to a frontside component; and
a power rail barrier connecting the first dielectric spacer and the second dielectric spacer and electrically separating the top power rail from the bottom power rail.

17. The semiconductor device as recited in claim 16, wherein the bottom power rail connects to a bottom source/drain region.

18. The semiconductor device as recited in claim 16, wherein the top power rail connects to a top source/drain region.

19. The semiconductor device as recited in claim 16, wherein the bottom power rail and the top power rail together provide positive and negative supply voltages.

20. The semiconductor device as recited in claim 16, wherein the bottom power rail and the top power rail provide a same supply voltage.
